(19) United States
(12) Patent Application Publication
(10) Pub. No.: US 2023/0326981 A1
(43) Pub. Date: Oct. 12, 2023

(54) SEMICONDUCTOR DEVICE AND MANUFACTURING METHOD THEREOF

(71) Applicant: GaNrich Semiconductor Corporation, Hsinchu City (TW)

(72) Inventors: Chih-Hao Chen, Hsinchu City (TW); Yi-Ru Shen, Yunlin County (TW)

(73) Assignee: GaNrich Semiconductor Corporation, Hsinchu City (TW)

(21) Appl. No.: 18/132,958

(22) Filed: Apr. 10, 2023

(30) Foreign Application Priority Data
Apr. 11, 2022 (CN) 202210377055.9

(51) Int. Cl. H01L 29/40; H01L 29/778; H01L 29/20; H01L 29/66

(52) U.S. Cl. CPC H01L 29/402; H01L 29/7786; H01L 29/2003; H01L 29/66462; H01L 29/401

(57) ABSTRACT

A semiconductor device includes a substrate, a semiconductor stack, an insulating structure, and an electrode. The semiconductor stack is disposed on the substrate and includes a two-dimensional electron gas region. The insulating structure is disposed on the semiconductor stack and includes a first insulating layer and a second insulating layer. The first insulating layer includes a first opening exposing the first inner sidewall of the first insulating layer. The second insulating layer is disposed on the first insulating layer and covers the first inner sidewall of the first insulating layer. The second insulating layer includes a second opening disposed in the first opening and exposing the second inner sidewall of the second insulating layer. The second insulating layer includes a step profile, and a step edge of the step profile coincides with the second inner sidewall. The electrode is disposed on the insulating structure and in the second opening.

### BACKGROUND OF THE INVENTION

### 1. Field of the Invention

The present disclosure relates to a semiconductor device, and more particularly to a semiconductor device including a field plate and a manufacturing method thereof

### 2. Description of the Prior Art

In semiconductor technology, group III-V compound semiconductor, such as gallium nitride (GaN), has the material characteristics of low on-resistance and high breakdown voltage. A high electron mobility transistor (HEMT) made of the group III-V compound semiconductor can be used to construct various integrated circuit (IC) devices, such as high-power field effect transistors or high-frequency transistors. A HEMT includes compound semiconductor layers with different energy band gaps, such as a high energy band gap semiconductor layer and a low energy band gap semiconductor layer, which are stacked on each other thereby generating a heterojunction between the semiconductor layers. This heterojunction with discontinuous energy band cause two-dimensional electron gas (2-DEG) to be formed near the heterojunction, and the 2-DEG can be used to transport carriers in the HEMT. Compared with conventional MOSFETs, HEMTs have many attractive characteristics, such as high electron mobility and the ability to transmit signals at high-frequency, because HEMTs use 2-DEG instead of a doped region as the carrier channel of MOSFETs.

For conventional HEMTs, a field plate is generally used to modulate the electric field distribution and/or the value of the peak electric field in the compound semiconductor layers, so as to avoid the electrical breakdown of the HEMT during operation. However, the structure of the compound semiconductor layer is often damaged during the process of manufacturing the field plate, which deteriorates the electrical properties of the compound semiconductor layer and thus affects the performance in electrical characteristic of the corresponding HEMT.

### SUMMARY OF THE INVENTION

In view of this, it is necessary to provide an improved semiconductor device to improve the defects of conventional semiconductor devices.

According to some embodiments of the present disclosure, a semiconductor device is disclosed and includes a substrate, a semiconductor stack, an insulating structure, and an electrode. The semiconductor stack is disposed on the substrate and includes a two-dimensional electron gas region. The insulating structure is disposed on the semiconductor stack and includes a first insulating layer and a second insulating layer. The first insulating layer includes a first opening exposing a first inner sidewall of the first insulating layer. The second insulating layer is disposed on the first insulating layer and covers the first inner sidewall of the first insulating layer. The second insulating layer includes a second opening disposed in the first opening and exposing a second inner sidewall of the second insulating layer. The second insulating layer includes a step profile, and a step edge of the step profile coincides with the second inner sidewall. The electrode is disposed on the insulating structure and in the second opening.

According to some embodiments of the present disclosure, a method of manufacturing a semiconductor device is disclosed, which includes the following steps: providing a substrate; disposing a semiconductor stack on the substrate, where the semiconductor stack includes a two-dimensional electron gas region; disposing a first insulating layer on the semiconductor stack; etching the first insulating layer to form a first opening; disposing a second insulating layer on the first insulating layer, where the second insulating layer is filled into the first opening; etching the second insulating layer to form a second opening in the first opening; and disposing at least one metal material on the second insulating layer to form an electrode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor device according to one embodiment of the present disclosure, where the semiconductor device includes two insulating layers.

FIG. 2 is a schematic cross-sectional view of a partial region of a semiconductor device according to one embodiment of the present disclosure.

FIG. 3 is a schematic cross-sectional view of a semiconductor device according to a modified embodiment of the present disclosure, where the semiconductor device includes three insulating layers.

FIG. 4 is a schematic cross-sectional view of a semiconductor device according to a modified embodiment of the present disclosure, where an electrode in the semiconductor device penetrates through a protective layer.

FIG. 5 is a schematic cross-sectional view of a semiconductor device according to a modified embodiment of the present disclosure, where an insulating structure in the semiconductor device directly contacts a semiconductor layer.

FIG. 6 to FIG. 9 are schematic cross-sectional views of a method of manufacturing a semiconductor device according to one embodiment of the present disclosure.

FIG. 10 is a schematic cross-sectional view of a method of manufacturing a semiconductor device according to a modified embodiment.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “over,” “above,” “upper”, “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second, ” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

In the present disclosure, a “group III-V semiconductor” refers to a compound semiconductor that includes at least one group III element and at least one group V element, where group III element may be boron (B), aluminum (Al), gallium (Ga) or indium (In), and group V element may be nitrogen (N), phosphorous (P), arsenic (As), or antimony (Sb). Furthermore, the group III-V semiconductor may refer to binary semiconductor, ternary semiconductor, quaternary semiconductor, compound semiconductor beyond quaternary semiconductor, or a combination thereof, but not limited thereto. For example, the group III-V semiconductor is binary semiconductor, such as aluminum nitride (AlN), gallium nitride (GaN), indium phosphide (InP), aluminum arsenide (AlAs), or gallium arsenide (GaAs), ternary semiconductor, such as aluminum gallium nitride (AlGaN), indium gallium nitride (InGaN), gallium indium phosphide (GaInP), aluminum gallium arsenic (AlGaAs), indium aluminum arsenic (InAlAs), or indium gallium arsenic (InGaAs), or quaternary semiconductor such as indium aluminum gallium nitride (InAlGaN). Besides, based on different requirements, group III-V semiconductor may contain dopants to become semiconductor with specific conductivity type, such as N-type or P-type.

Although the disclosure is described with respect to specific embodiments, the principles of the invention, as defined by the claims appended herein, can obviously be applied beyond the specifically described embodiments of the invention described herein. Moreover, in the description of the present disclosure, certain details have been left out in order to not obscure the inventive aspects of the disclosure. The details left out are within the knowledge of a person of ordinary skill in the art.

The present disclosure relates to a semiconductor device, such as a high electron mobility transistor (HEMT) including a field plate.

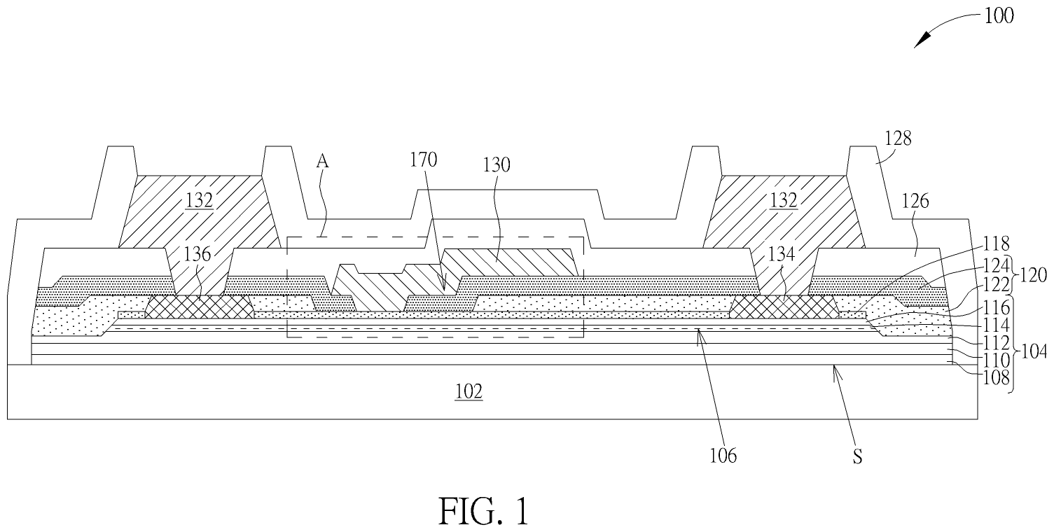

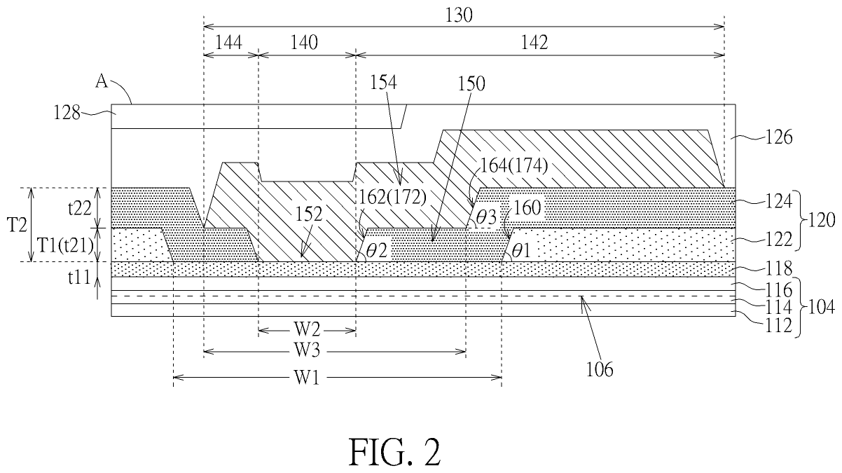

FIG. 1 is a schematic cross-sectional view of a semiconductor device according to one embodiment of the present disclosure, where the semiconductor device includes two insulating layers. FIG. 2 is a schematic cross-sectional view of a partial region of a semiconductor device according to one embodiment of the present disclosure. Referring to FIG. 1, a semiconductor device 100, such as a high electron mobility transistor or other high-voltage power transistor device, includes a substrate 102, a semiconductor stack 104, an insulating structure 120, and an electrode 130 stacked in sequence. The semiconductor stack 104 is disposed on the substrate 102 and includes a two-dimensional electron gas region 106. The insulating structure 120 is disposed on the semiconductor stack 104, and the insulating structure 120 may be a stacked structure, for example, including a first insulating layer 122 and a second insulating layer 124. Referring to FIG. 2, which is an enlarged schematic view of a partial region Ain FIG. 1, the first insulating layer 122 includes a first opening 150, and the first opening 150 exposes a first inner sidewall 160 of the first insulating layer 122. The second insulating layer 124 is disposed on the first insulating layer 122 and covers the first inner sidewall 160 of the first insulating layer 122. The second insulating layer 124 includes a second opening 152, which is located in the first opening 150 and exposes a second inner sidewall 162 of the second insulating layer 124. Referring to FIG. 1, the second insulating layer 124 includes a step profile 170. Referring to FIG. 2, the step edge 172 of the step profile coincides with the second inner sidewall 162 of the second insulating layer 124. The electrode 130 is disposed on the insulating structure 120 and located in the second opening 152.

Referring to FIG. 1 and FIG. 2, according to some embodiments of the present disclosure, since the second insulating layer 124 of the semiconductor device 100 covers the first inner sidewall 160 of the first insulating layer 122, and the second opening 152 of the second insulating layer 124 is disposed in the first opening 150 of the first insulating layer 122, the bottom surface of the electrode 130 can be raised up along a certain direction to have a step edge with different bottom heights when the electrode 130 is disposed on the insulating structure 120. When a predetermined bias voltage is applied to the electrode 130, the electrode 130 whose bottom surface is at different heights may generate different electric field intensity to the corresponding underlying semiconductor stack 104, thus effectively redistributing the electric field in the semiconductor stack 104 and further improving the capability of the semiconductor device 100 to withstand voltage.

In addition to the above components and layers, the semiconductor device 100 may further include other optional components and layers. The components and layers of the semiconductor device 100 are further described below.

Referring to FIG. 1, a semiconductor device 100 includes a substrate 102, and the substrate 102 includes a surface S, such as a topmost surface. The substrate 102 may be an epitaxial substrate (such as a bulk silicon substrate, a silicon carbide (SiC) substrate, an aluminum nitride (AlN) substrate, or a sapphire substrate), a ceramic substrate, or a semiconductor on insulator substrate (such as a silicon-on-insulator (SOI) substrate or a germanium-on-insulator (GOI) substrate). The thickness of the substrate 102 is 500 μm to 2 mm, such as 670 μm to 1000 μm, but not limited thereto. According to some embodiments of the present disclosure, the whole or the surface of the substrate 102 can be electrically insulating, thus further avoiding unnecessary electrical connection between structures respectively arranged above and below the substrate 102. However, according to some embodiments of the present disclosure, the substrate 102 can also have conductivity and is not limited to an insulating substrate.

The semiconductor stack 104 is disposed on the surface S of the substrate 102 and includes a plurality of group III-V semiconductor layers. For example, the semiconductor stack 104 includes a base layer 108, a buffer layer 110, a high-resistance layer 112, a channel layer 114, and a barrier layer 116 from bottom to top. The base layer 108 is a group III-V semiconductor layer, such as AlN or other nitride semiconductor layers, which can make the semiconductor layer disposed above the base layer 108 have better crystallinity. The buffer layer 110 can be used to reduce the degree of stress or lattice mismatch between the substrate 102 and the semiconductor stack 104. The buffer layer 110 can include a plurality of group III-V sub-semiconductor layers, which can form composition ratio gradient layers or a super lattice structure. In this case, the composition ratio gradient layer means that the composition ratio of the sub-semiconductor layers adjacent to each other can continuously change along a certain direction, such as aluminum gallium nitride (AlₓGa₍₁₋ₓ₎N) with gradually changed composition ratio, and the value of x may decrease from 0.9 to 0.15 in a continuous or stepwise manner along the direction away from the substrate 102. The super lattice structure includes alternately stacked sub-semiconductor layers with different composition ratios, and these sub-semiconductor layers are adjacent to each other and appear in pairs (for example, paired Alₓ₁Ga₍₁₋ₓ₁₎N and Alₓ₂Ga₍₁₋ₓ₂₎N, 0.1>X1−X2>0.01) as the smallest repeating unit in the super lattice structure.

The high-resistance layer 112 is disposed on the substrate 102, for example, disposed on the buffer layer 110. Compared with other layers, the high-resistance layer 112 has higher resistivity, so current leakage between the semiconductor layer disposed on the high-resistance layer 112 and the substrate 102 can be avoided. For example, the high-resistance layer 112 may be a group III-V semiconductor layer with dopants, such as carbon-doped gallium nitride (c-GaN), but not limited thereto.

The channel layer 114 is disposed on the substrate 102, for example, disposed on the high-resistance layer 112. The channel layer 114 may include one or more group III-V semiconductor layers, and the composition of the group III-V semiconductor layers may be GaN, AlGaN, InGaN or InAlGaN, but not limited thereto. For example, the channel layer 114 is an undoped group III-V semiconductor, such as undoped-GaN (u-GaN).

The barrier layer 116 is disposed on the channel layer 114. The barrier layer 116 may include one or more group III-V semiconductor layers, and the composition thereof may be different from that of the channel layer 114. For example, the material of the barrier layer 116 may include a material with a larger energy band gap than an energy band gap of the channel layer 114, such as AlN, AlₓGa₍₁₋ₓ₎N (0<x<1) or a combination thereof. According to one embodiment of the present disclosure, the barrier layer 116 may be an N-type group III-V semiconductor, such as an intrinsic N-type AlGaN layer, but not limited thereto.

Because an energy band gap between the channel layer 114 and the barrier layer 116 is discontinuous, a potential well can be formed in the channel layer 114 near the heterojunction between the channel layer 114 and the barrier layer 116 by stacking the channel layer 114 and the barrier layer 116 with each other. Electrons can be accumulated in the potential well due to the piezoelectric effect, thus producing a sheet with high electron mobility, i.e., two-dimensional electron gas (2-DEG) region 106.

According to different requirements, the arrangement order of the base layer 108, the buffer layer 110, and the high-resistance layer 112 in the semiconductor stack 104 can be adjusted instead of being limited to the above, and at least some of these layers can be repeated, omitted, or replaced by other semiconductor layers. Other group III-V semiconductor layers may also be included in the semiconductor stack 104. Therefore, the channel layer 114 and the barrier layer 116 can be single-crystalline grown on the substrate 102 and having few or almost no lattice defects.

The protective layer 118 is disposed on the semiconductor stack 104 between the insulating structure 120 and the semiconductor stack 104. The protective layer 118 can be used to eliminate or reduce the surface defects on the top surface of the barrier layer 116, thereby improving the electron mobility of the two-dimensional electron gas region 106. The protective layer 118 can also be used to protect the underlying semiconductor stack 104 to protect the semiconductor stack 104 from damages during etching. The conductivity of the protective layer 118 is lower than the conductivity of the barrier layer 116, and the material of the protective layer 118 is different from the material of the insulating structure 120, such as an insulating layer or a group III-V semiconductor layer. The insulating layer includes silicon nitride (SiN), and the group III-V semiconductor layer includes gallium nitride.

An insulating structure 120 is disposed on the protective layer 118. The insulating structure 120 includes an opening exposing the underlying protective layer 118. The electrode 130 can be filled into the opening of the insulating structure 120 and directly contact the protective layer 118. According to some embodiments of the present disclosure, the second opening 152 of the second insulating layer 124 exposes the underlying protective layer 118, and the electrode 130 is filled into the second opening 152 and contacts the protective layer 118. The drain electrode 134 and the source electrode 136 are respectively disposed on both sides of the electrode 130 and covered by the insulating structure 120, where the first insulating layer 122 and the second insulating layer 124 respectively include two openings to respectively expose the drain electrode 134 and the source electrode 136 underneath. In some embodiments, the protective layer 118 includes two openings, through which the drain electrode 134 and the source electrode 136 are electrically connected to the underlying semiconductor layer, such as the channel layer 114 and/or the barrier layer 116, respectively, and ohmic contact is thus formed. The two openings of the first insulating layer 122 and the two openings of the second insulating layer 124 can be formed in different processes or formed concurrently in the same process.

A plurality of interlayer dielectric layers, such as a first intermediate dielectric layer 126 and a second intermediate dielectric layer 128, are disposed on the insulating structure 120. The intermediate dielectric layers may have the same or different materials, such as SiN, AlN, Al₂O₃, SiON or SiO₂, but not limited thereto. The first intermediate dielectric layer 126 covers the electrode 130 (including the gate electrode and the field plate) and includes two openings to respectively expose the drain electrode 134 and the source electrode 136. At least two bond pad structures 132 are disposed on the drain electrode 134 and the source electrode 136 respectively, and are electrically connected to the drain electrode 134 and the source electrode 136 through two openings in the first intermediate dielectric layer 126 and the two openings in the second insulating layer 124. The two openings in the second insulating layer 124 and the two openings in the first intermediate dielectric layer 126 can be formed in different processes or formed concurrently in the same process. The second intermediate dielectric layer 128 covers the first intermediate dielectric layer 126, the sidewall of the semiconductor stack 104, and the two bond pad structures 132. The second intermediate dielectric layer 128 includes two openings exposing a top surface of the bond pad structures 132, and the exposed top surface can act as regions through which the semiconductor device 100 and external devices are electrically connected. The semiconductor device 100 may also include another bond pad structure (not shown) electrically connected to the electrode 130.

The components in the region A of FIG. 1 are further described below. FIG. 2 is a schematic cross-sectional view of a partial region of a semiconductor device according to one embodiment of the present disclosure, such as an enlarged schematic view of the region A in FIG. 1. Referring to FIG. 2, the insulating structure 120 includes the first insulating layer 122 and the second insulating layer 124 disposed on the protective layer 118. The first insulating layer 122 includes the first opening 150, and the bottom of the first opening 150 has a first width W1. The first opening 150 may expose the first inner sidewall 160 of the first insulating layer 122. A first included angle θ1, such as an acute angle of no more than 70 degrees, is between the first inner sidewall 160 and the surface of the protective layer 118 (or the surface of the substrate).

The second insulating layer 124 is conformally disposed on the surface of the first insulating layer 122, so that a portion of the second insulating layer 124 is disposed in the first opening 150, and the other portions of the second insulating layer 124 are disposed outside the first opening 150. In addition to the second opening 152, the second insulating layer 124 further includes a third opening 154 disposed above the second opening 152, and the third opening 154 is disposed above the first opening 150. The bottom of the second opening 152 has a second width W2, and the second opening 152 exposes the second inner sidewall 162 of the second insulating layer 124. A second included angle θ2, such as an acute angle of no more than 70 degrees and/or no less than 45 degrees, is between the second inner sidewall 162 and the surface of the protective layer 118 (or the surface of the substrate). However, the second included angle θ2 may also be less than 45 degrees according to different requirements. The bottom surface of the third opening 154 has a third width W3, and the third opening 154 exposes a third inner sidewall 164 of the second insulating layer 124. A third included angle θ3, such as an acute angle of no more than 70 degrees and/or no less than 45 degrees, is between the third inner sidewall 164 and the surface of the protective layer 118 (or the surface of the substrate). However, the third included angle θ3 may also be less than 45 degrees according to different requirements. The second inner sidewall 162 and the third inner sidewall 164 are sequentially arranged from bottom to top, so that the step edges 172, 174 of the step profile of the second insulating layer 124 coincides with the second inner sidewall 162 and the third inner sidewall 164, respectively. In addition, the third width W3 of the third opening 154 is between the first width W1 of the first opening 150 and the second width W2 of the second opening 152.

The first included angle θ1, the second included angle θ2 and the third included angle θ3 are all acute angles, which are 20-60 degrees, 20-65 degrees and 20-70 degrees, respectively, and the first included angle θ1 is less than or equal to the third included angle θ3, and the second included angle θ2 may be less than or equal to the third included angle θ3.

The first insulating layer 122 has a first thickness t21, such as 150 nm to 500 nm, and the second insulating layer 124 has a second thickness t22, such as 100 nm to 400 nm. The first thickness t21 of the first insulating layer 122 is greater than the second thickness t22 of the second insulating layer 124, and the first thickness t21 is greater than the thickness t11 of the protective layer 118. Regarding a whole of the insulating structure 120, the first insulating layer 122 adjacent to the second opening 152 and located in the first opening 150 may exhibit a first step thickness T1, while the first insulating layer 122 and the second insulating layer 124 stacked on each other exhibit a second step thickness T2, so that the second step thickness T2 is greater than the first step thickness T1.

The electrode 130 is filled into the second opening 152 and extends outward from the second opening 152, and extends at least along a direction toward the drain electrode (not shown). The electrode 130 includes a main portion 140, a first extension portion 142, and a second extension portion 144. The main portion 140 serves as a gate electrode of the semiconductor device 100. When a predetermined bias voltage is applied to the main portion 140, the concentration of the two-dimensional electron gas 106 in the channel layer 114 directly below the main portion 140 can be modulated, thereby conducting or cutting off the current of the semiconductor device 100. The first extension portion 142 is disposed on the second insulating layer 124, and the bottom surface of the first extension portion 142 is raised up along the direction away from the second opening 152. The first extension portion 142 serves as a field plate of the semiconductor device 100 to modulate the distribution of electric field and/or the peak value of electric field of the underlying semiconductor stack 104. Because a portion of the first extension portion 142 is closer to the semiconductor stack 104, while other portions of the first extension portion 142 are farther away from the semiconductor stack 104, electric field with different electric field intensity can be generated on the corresponding underlying semiconductor stack 104 when a predetermined bias voltage is applied to the first extension portion 142, which effectively redistributes the electric field distribution in the semiconductor stack 104 and further improves the withstand voltage of the semiconductor device 100. The second extension portion 144 is disposed on the second insulating layer 124, which is used to ensure that the electrode 130 can still be filled into the second opening 152 even when misalignment occurs during the manufacturing process.

Regarding the second insulating layer 124 in the insulating structure 120, since the second included angle θ2 and the third included angle θ3 of the second insulating layer 124 are acute angles, the first extending portion 142 disposed above the second insulating layer 124 generate not only longitudinal electric field but also transversal electric field to the underlying semiconductor stack 104, so that the electric field distribution in the semiconductor stack 104 can be regulated and controlled more effectively. In this way, the electric field peak becomes away from the bottom edge of the main portion 140, thereby avoiding the electrical breakdown of the semiconductor device 100.

According to some embodiments of the present disclosure, when the protective layer 118 is an insulating layer, the electrode 130 in the second opening 152, the protective layer 118 right below the second opening 152, and the channel layer 114 right below the second opening 152 can constitute a capacitor structure with metal-insulator-semiconductor (MIS). In this case, during the operation of the semiconductor device 100, the current can be blocked by the protective layer 118 and does not flow between the electrode 130 and the channel layer 114, thus avoiding current leakage. According to some embodiments of the present disclosure, when the protective layer 118 is a semiconductor layer, the electrode 130 located in the second opening 152 and the protective layer 118 right below the second opening 152 can constitute a Schottky contact structure. In this case, during the operation of the semiconductor device 100, the current does not easily flow through the electrode 130 due to the energy barrier of the Schottky contact structure, thus avoiding the current leakage.

In addition to the above embodiments, the semiconductor device of the present disclosure may include other embodiments and is not limited to the foregoing embodiments. In the following paragraphs, various modifications and variations about semiconductor transistors are disclosed and the description below is mainly focused on differences among these embodiments. In addition, the present disclosure may repeat reference numerals and/or letters in the various modifications and variations. This repetition is for the purpose of simplicity and clarity and does not in itself dictate a relationship between the various embodiments and/or configurations discussed.

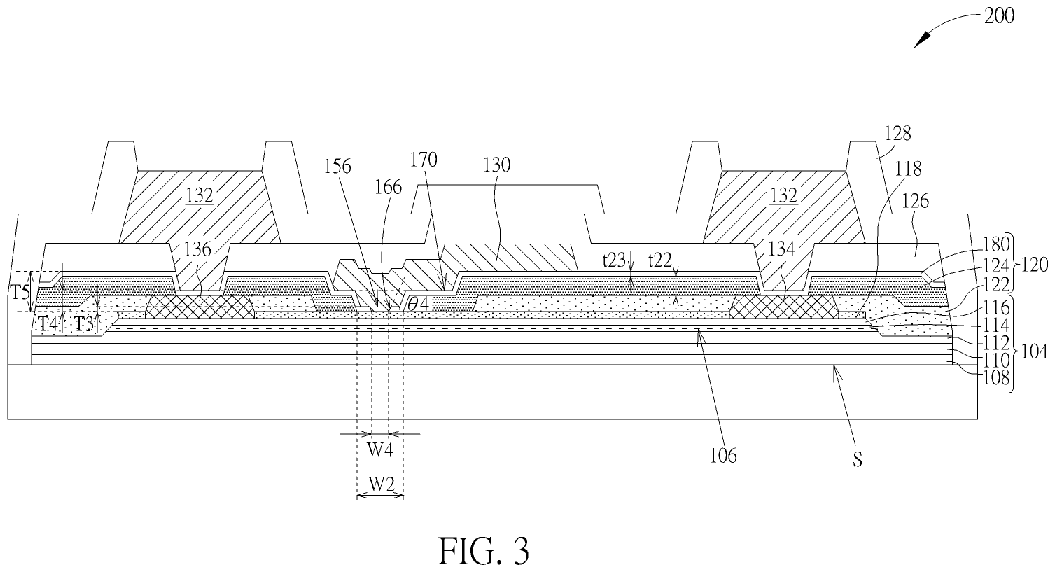

FIG. 3 is a schematic cross-sectional view of a semiconductor device according to one modified embodiment of the present disclosure, where the semiconductor device includes three insulating layers. Referring to FIG. 3, the structure of the semiconductor device 200 in FIG. 3 is similar to the structure of the semiconductor device 100 shown in FIG. 1. The main difference between the two embodiments is that the insulating structure 120 in the semiconductor device 200 in FIG. 3 includes not only the first insulating layer 122 and the second insulating layer 124, but also a third insulating layer 180 conformally disposed on the second insulating layer 124 and partially filled into the second opening 152. The third insulating layer 180 has a third thickness t23, which may be smaller than the second thickness t22 of the second insulating layer 124. The third insulating layer 180 includes a fourth opening 156, and the fourth opening 156 exposes a fourth inner sidewall 166 of the third insulating layer 180. The bottom surface of the fourth opening 156 has a fourth width W4 which is smaller than the second width W2 of the second opening 152. The electrode 130 is disposed on the third insulating layer 180, so that the bottom surface of the electrode 130 is raised up along the direction away from the fourth opening 156 to thereby have a step profile. By providing the third insulating layer 180, the insulating structure 120 can have thicknesses (for example, a third step thickness T3, a fourth step thickness T4, and a fifth step thickness T5) which are increased sequentially to have a step profile, and the main portion 140 of the electrode 130 can also have different heights, thus exhibiting the efficacy of a field plate. Thus, the electrode 130 (i.e., the electrode 130 right above the third insulating layer 180) can have three unequal heights, which can modulate the electric field distribution in the semiconductor stack 104 more effectively.

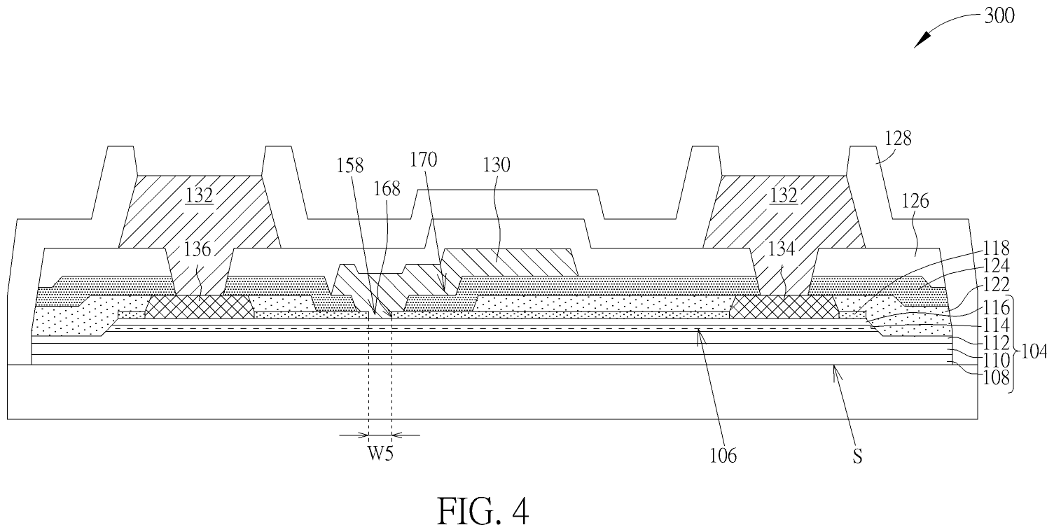

FIG. 4 is a schematic cross-sectional view of a semiconductor device according to one modified embodiment of the present disclosure, in which electrodes in the semiconductor device penetrate through a protective layer. Referring to FIG. 4, the structure of the semiconductor device 300 in FIG. 4 is similar to the structure of the semiconductor device 100 in FIG. 1. The main difference between the two embodiments is that the protective layer 118 of the semiconductor device 300 in FIG. 4 has a fifth opening 158 exposing the underlying semiconductor stack 104 (such as the barrier layer 116) and a fifth inner sidewall 168 of the protective layer 118. By providing the fifth opening 158 in the protective layer 118, the electrode 130 can be filled into the fifth opening 158 and directly contact the barrier layer 116 below, so that a Schottky contact may be occurred between the electrode 130 and the barrier layer 116. By providing the fifth opening 158 in the protective layer 118, the main portion 140 of the electrode 130 also has different heights, thus exhibiting the effect of a field plate. Thus, the electrode 130 (i.e., the electrode 130 directly above the protective layer 118 and the second insulating layer 124 respectively) can have three unequal heights, which can modulate the electric field distribution in the semiconductor stack 104 more effectively. A fifth included angle is between the fifth inner sidewall 168 and the semiconductor stack 104, wherein the fifth included angle may be larger than the first included angle, the second included angle, the third included angle, or the fourth included angle.

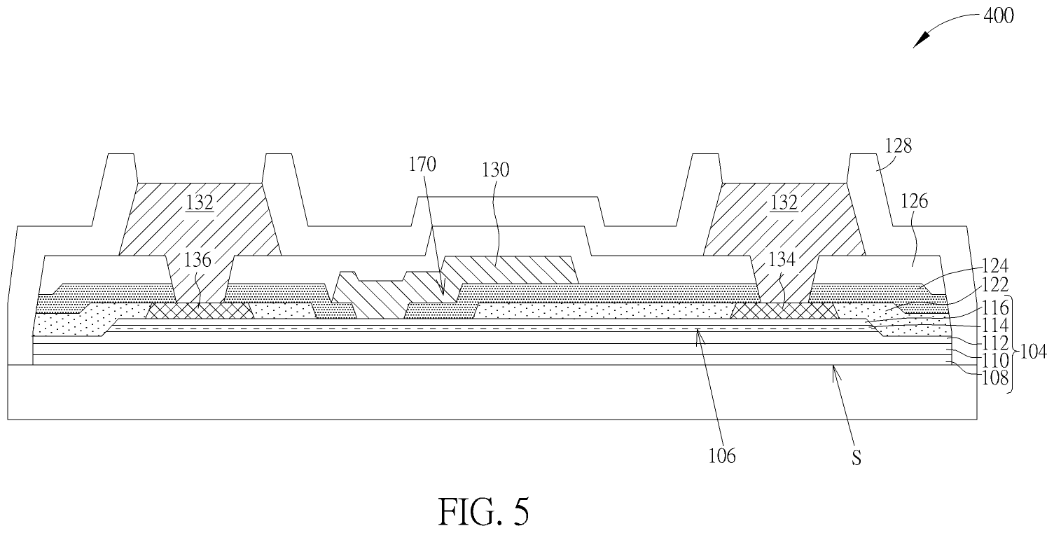

FIG. 5 is a schematic cross-sectional view of a semiconductor device according to one modified embodiment of the present disclosure, in which an insulating structure in the semiconductor device directly contacts a semiconductor layer. Referring to FIG. 5, the structure of the semiconductor device 400 in FIG. 5 is similar to the structure of the semiconductor device 100 in FIG. 1. The main difference between the two embodiments is that the semiconductor device 400 in FIG. 5 is not provided with the protective layer 118, so the insulating structure 120 and the electrode 130 can directly contact the semiconductor stack 104.

In order to enable one of ordinary skill in the art to implement inventions of the disclosure, the manufacturing method of the semiconductor device is further described in detail below.

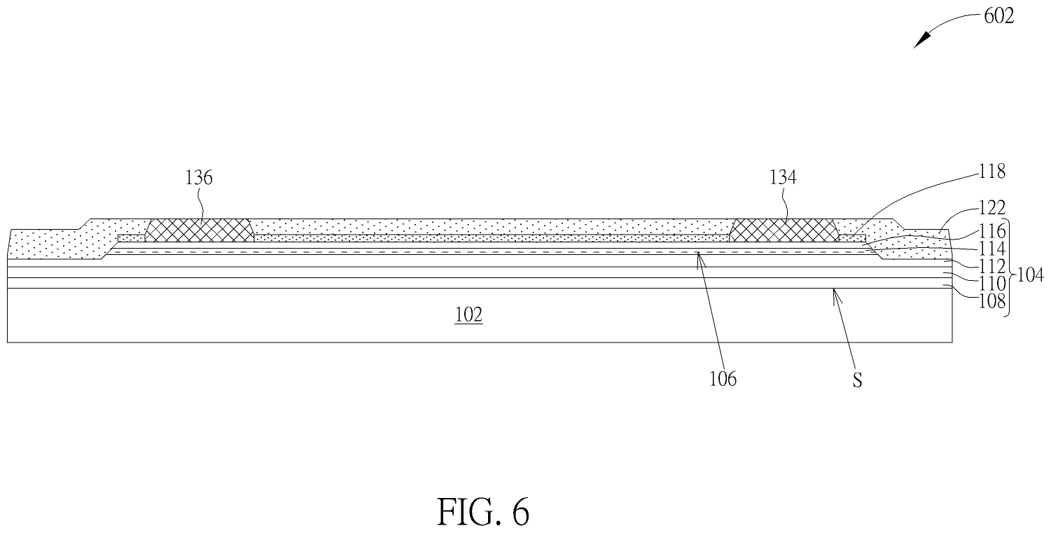

FIG. 6 to FIG. 9 are schematic cross-sectional views of a method of manufacturing a semiconductor device according to one embodiment of the present disclosure. Referring to the cross-sectional view 602 of FIG. 6, at this stage of manufacture, semiconductor layers in a semiconductor stack 104 are sequentially formed on a surface S of a substrate 102 by an epitaxial or deposition process. For example, molecular-beam epitaxy (MBE), metal-organic chemical vapor deposition (MOCVD), hydride vapor phase epitaxy (HVPE), atomic layer deposition (ALD), or other suitable methods can be adopted to form each semiconductor layer in the semiconductor stack 104. After the semiconductor stack 104 is formed, a protective material layer (a protective layer 118) is formed on the semiconductor stack 104, for example, by performing an epitaxial process or a deposition process, followed by a subsequent etching process to form the protective layer 118. In the subsequent etching process, the protective layer 118 may serve as an etch stop layer. In addition, the protective layer 118 may also be used as a passivation layer to protect the underlying semiconductor stack 104. For example, the material of the protective layer 118 includes nitride (such as silicon nitride (SiN), aluminum nitride (AlN), or gallium nitride (GaN)), oxide (such as aluminum oxide (Al₂O₃) or silicon oxide (SiOₓ)), or oxynitride (such as silicon oxynitride (SiON)), but not limited thereto. Then, an etching process is performed to remove a portion of the protective material layer (the protective layer 118) and a portion of the semiconductor layer (the semiconductor stack 104) to form a protruding mesa, which can be used to accommodate electrodes of semiconductor devices, such as a gate electrode, source electrode and drain electrode. Subsequently, a portion of the protective material layer (the protective layer 118) can be etched through to expose the underlying barrier layer 116, or the barrier layer 116 can be further etched through to expose the channel layer 114 and form an opening in the protective layer 118.

Then, a drain electrode 134 and a source electrode 136 are formed to be filled into the openings in the protective layer 118. In addition, a suitable heat treatment process, such as a heat treatment process with a temperature higher than 300° C., can be performed to generate ohmic contact between the drain electrode 134 and the source electrode 136 and at least one of the barrier layer 116 and the channel layer 114 below. The materials of the drain electrode 134 and the source electrode 136 include metal, alloy or stacked layers thereof. The stacked layers may be, for example, Ti/Al, Ti/Al/Ti/TiN, Ti/Al/Ti/Au, Ti/Al/Ni/Au or Ti/Al/Mo/Au, but not limited thereto.

Then, a deposition process, such as a vapor deposition process, is performed to form the first insulating material layer (a first insulating layer 122) covering the semiconductor stack 104 and the protective layer 118, and the first insulating layer 122 can be formed by performing the subsequent etching process. The material of the first insulating layer 122 is different from the material of the protective layer 118. For example, the material of the first insulating layer 122 includes nitride, such as silicon nitride (SiN) or aluminum nitride (AlN), oxide, such as aluminum oxide (Al₂O₃) or silicon oxide (SiOx), or oxynitride, such as silicon oxynitride (SiON), but not limited thereto. In addition, the first insulating layer 122 is not limited to a single-layer structure, but can be a multi-layer stacked structure.

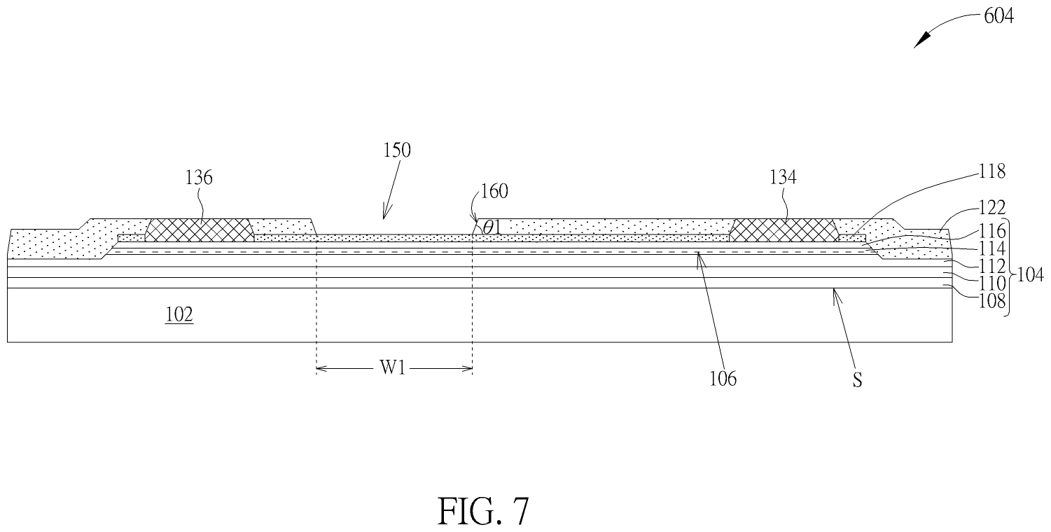

Subsequently, after the stage of manufacture shown in FIG. 6 is completed, referring to a cross-sectional view 604 shown in FIG. 7, photolithography and etching processes are performed to form a first opening 150 in the first insulating material layer to thereby form the first insulating layer 122, and the first opening 150 exposes the underlying protective layer 118. The etching process is a dry etching process or wet etching process, for example. A first inner sidewall 160 of the first insulating layer 122 formed by the etching process is inclined rather than vertical, so that the first inner sidewall 160 has a first included angle θ1 with respect to the underlying protective layer 118 (or the surface of the substrate), and the first included angle θ1 is an acute angle. In some embodiments of the present disclosure, the first insulating layer 122 can be etched to form the inclined first inner sidewall 160 by inherent lateral etching during the wet etching process. In addition, under a selected wet etching condition, the protective layer 118 can act as an etch stop layer, that is, the etching rate of the etchant for the protective layer 118 can be lower than the etching rate of the etchant for the first insulating layer 122, so that the etching selectivity ratio between the protective layer 118 and the first insulating layer 122 is less than 1, such as 0.95, 0.65, 0.35, 0.05, 0.01, 0.005, or any values therebetween. According to some embodiments of the present disclosure, when the material of the first insulating layer 122 is silicon oxide and the material of the protective layer 118 is silicon nitride, a buffered oxide etch (BOE) can be used to form the first opening 150 in the first insulating layer 122 without forming opening or recess in the protective layer 118.

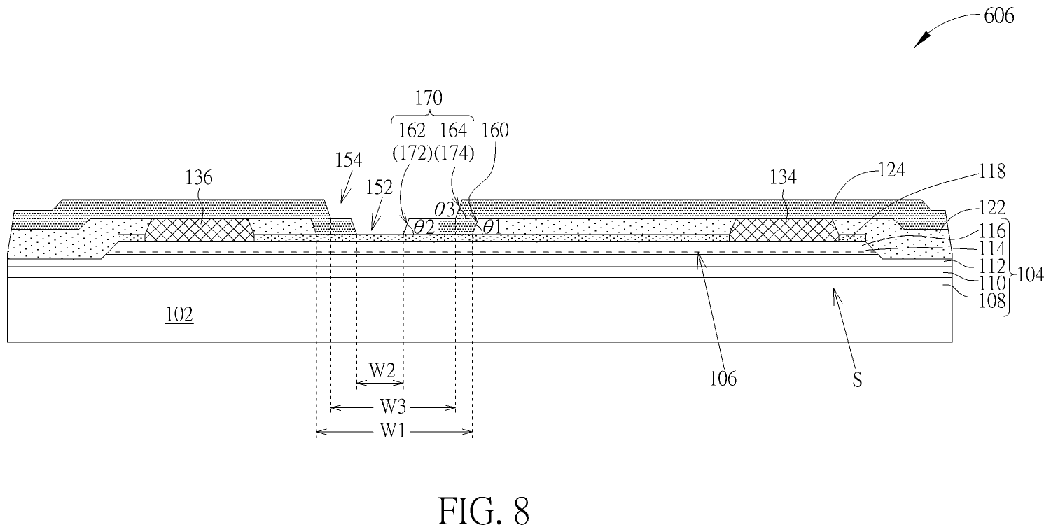

Then, referring to cross-sectional view 606 of FIG. 8, a deposition process such as vapor deposition process is performed to form a second insulating material layer conformally covering the first insulating layer 122, and then a second insulating layer 124 is formed by performing a subsequent etching process. The second insulating layer 124 has a third inner sidewall 164 adjacent to the first inner sidewall 160 of the first insulating layer 122. A third included angle θ3 is between the third inner sidewall 164 and the surface of the protective layer 118 (or the surface of the substrate), and the third included angle θ3 is an acute angle. The materials of the second insulating layer 124 and the first insulating layer 122 may be the same or different, and the material of the second insulating layer 124 may be different from the material of the protective layer 118. For example, the material of the second insulating layer 124 includes nitride, such as silicon nitride (SiN) or aluminum nitride (AlN), oxide, such as aluminum oxide (Al₂O₃) or silicon oxide (SiOₓ), or nitrogen oxide, such as silicon oxynitride (SiON), but not limited thereto. In addition, the second insulating layer 124 is not limited to a single-layer structure, but can be a multi-layer stacked structure.

Then, photolithography and etching processes are performed to form a second opening 152 in the second insulating material layer to thereby expose the underlying protective layer 118 from the second opening 152, and a process of forming the second insulating material layer is thereby completed. The second opening 152 is disposed in the first opening 150, and the second width W2 of the second opening 152 is smaller than the first width W1 of the first opening 150. The etching process is, for example, a dry etching process or wet etching process. The etching process of forming the second opening 152 in the second insulating layer 124 may be the same as or different from the etching process of forming the first opening 150 in the first insulating layer 122. Taking the wet etching process as an example, due to the inherent lateral etching during the wet etching process, a second inner sidewall 162 of the second insulating layer 124 is inclined rather than vertical, so that the second inner sidewall 162 has a second included angle θ2 with respect to the underlying protective layer 118 (or the surface of the substrate), where the second included angle θ2 is an acute angle. In addition, under a selected wet etching condition, the protective layer 118 may act as an etch stop layer, that is, the etching rate of the etchant for the protective layer 118 can be lower than the etching rate of the etchant for the second insulating layer 124, so that the etching selectivity ratio between the protective layer 118 and the second insulating layer 124 is less than 1, such as 0.95, 0.65, 0.35, 0.05, 0.01, 0.005, or any values therebetween. According to some embodiments of the present disclosure, when the material of the second insulating layer 124 is silicon oxide and the material of the protective layer 118 is silicon nitride, buffered oxide etch (BOE) can be used to form the second opening 152 in the second insulating layer 124 without forming opening or recess in the protective layer 118.

After the process of etching the second insulating layer 124 is completed, the second insulating layer 124 can exhibit a step profile 170, and step edges 172, 174 of the step profile 170 can coincide with the second inner sidewall 162 and the third inner sidewall 164 of the second insulating layer 124, respectively.

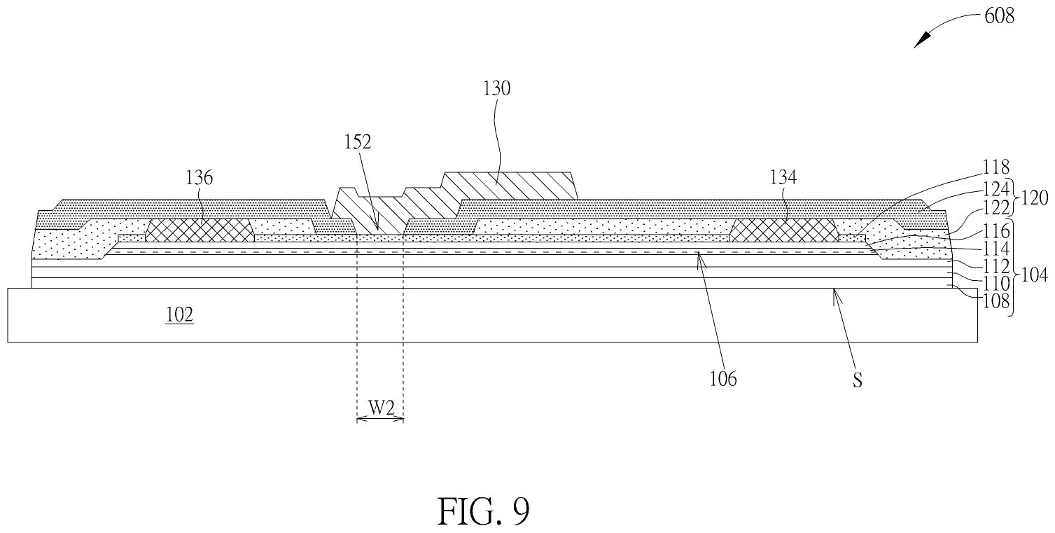

Then, referring to cross-sectional view 608 of FIG. 9, at least one metal material is disposed on the second insulating layer 124, and an appropriate patterning process is performed to form an electrode 130. The electrode 130 is filled into the second opening 152 of the second insulating layer 124. The electrode 130 can extend outward from the second opening 152 and has an asymmetric cross-sectional structure. The material of the electrode 130 may include metal, alloy, semiconductor material, or stacked layers thereof. For example, the electrode 130 may include gold (Au), nickel (Ni), platinum (Pt), palladium (Pd), iridium (Ir), titanium (Ti), chromium (Cr), tungsten (W), aluminum (Al), copper (Cu), molybdenum (Mo) and other suitable conductive materials. Then, photolithography and etching processes are performed to remove each layer in a predetermined region and to thereby expose the surface of a portion of the substrate 102.

After the stage of manufacture in FIG. 9 is completed, at least two intermediate dielectric layers and at least two bond pad structures can be formed on the electrode 130 and the second insulating layer 124, so that the bond pad structures are electrically connected to the drain electrode 134 and the source electrode 136 below the bond pad structures, respectively, and the semiconductor device 100 shown in FIG. 1 can be obtained.

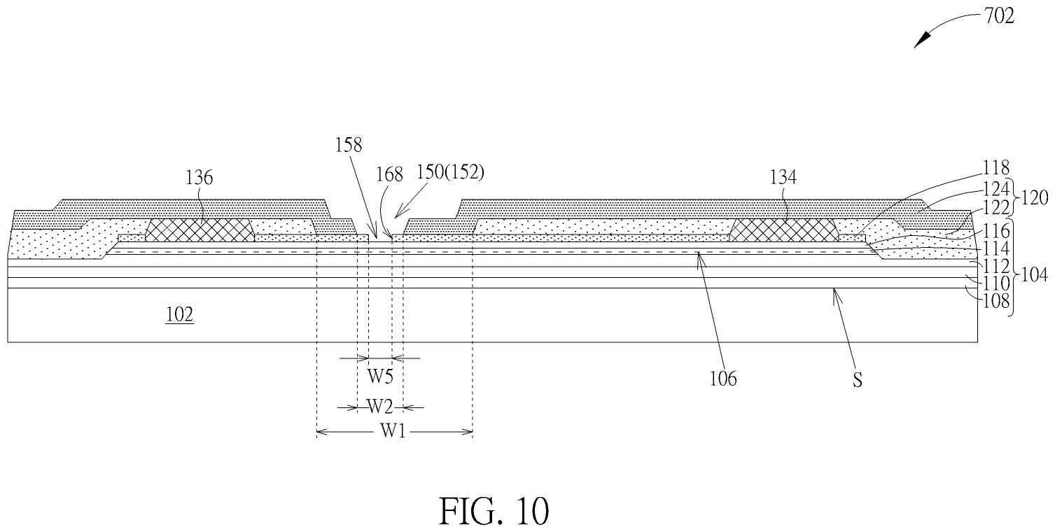

FIG. 10 is a schematic cross-sectional view of a method of manufacturing a semiconductor device according to one modified embodiment of the present disclosure. Referring to a cross-sectional view 702 of FIG. 10, the process shown in FIG. 10 is similar to the process shown in FIG. 8. The main difference between them is that, after the second opening 152 is formed in the second insulating layer 124, photolithography and etching processes are further performed to form a fifth opening 158 in the protective layer 118 to thereby expose the underlying semiconductor stack 104 and a fifth inner sidewall 168. The bottom surface of the fifth opening 158 has a fifth width W5 which is smaller than the second width W2 of the second insulating layer 124.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, comprising a surface;
a semiconductor stack, disposed on the substrate and comprising a two-dimensional electron gas region;
an insulating structure, disposed on the semiconductor stack and comprising:
a first insulating layer, comprising a first opening exposing a first inner sidewall of the first insulating layer; and
a second insulating layer, disposed on the first insulating layer and covering the first inner sidewall of the first insulating layer, wherein the second insulating layer comprises a second opening disposed in the first opening and exposing a second inner sidewall of the second insulating layer, wherein the second insulating layer comprises a step profile, and a step edge of the step profile coincides with the second inner sidewall; and
an electrode, disposed on the insulating structure and in the second opening.

2. The semiconductor device according to claim 1, wherein a portion of the second insulating layer is disposed in the first opening.

3. The semiconductor device according to claim 1, wherein the second insulating layer further comprises a third inner sidewall disposed above the second inner sidewall.

4. The semiconductor device according to claim 3, wherein the step profile of the second insulating layer comprises a further step edge, and the further step edge coincides with the third inner sidewall.

5. The semiconductor device according to claim 3, wherein the first inner sidewall, the second inner sidewall and the third inner sidewall form a first included angle, a second included angle and a third included angle with respect to the surface of the substrate respectively, wherein the second included angle is not equal to the third included angle.

6. The semiconductor device according to claim 5, wherein the second included angle is smaller than the third included angle.

7. The semiconductor device according to claim 5, wherein the first included angle, the second included angle and the third included angle are acute angles.

8. The semiconductor device according to claim 7, wherein the first included angle, the second included angle and the third included angle are not greater than 70 degrees.

9. The semiconductor device according to claim 1, wherein a material of the first insulating layer is the same as a material of the second insulating layer.

10. The semiconductor device according to claim 1, wherein a thickness of the first insulating layer is greater than a thickness of the second insulating layer, and the thicknesses of the first insulating layer and the second insulating layer are both greater than 100 nm.

11. The semiconductor device according to claim 1, wherein the second insulating layer further comprises a third opening disposed above the first opening and the second opening.

12. The semiconductor device according to claim 11, wherein a width of the third opening is between a width of the first opening and a width of the second opening.

13. The semiconductor device according to claim 1, further comprising a protective layer disposed between the insulating structure and the semiconductor stack, wherein materials of the protective layer and the insulating structure are different.

14. The semiconductor device according to claim 13, wherein the protective layer further comprises an opening exposing the semiconductor stack.

15. A method of manufacturing a semiconductor device, comprising:
providing a substrate;
disposing a semiconductor stack on the substrate, wherein the semiconductor stack comprises a two-dimensional electron gas region;
disposing a first insulating layer on the semiconductor stack;
etching the first insulating layer to form a first opening;
disposing a second insulating layer on the first insulating layer, wherein the second insulating layer is filled into the first opening;
etching the second insulating layer to form a second opening in the first opening; and
disposing at least one metal material on the second insulating layer to form an electrode.

16. The method of manufacturing a semiconductor device according to claim 15, wherein the steps of disposing the first insulating layer and the second insulating layer comprise a vapor deposition process.

17. The method of manufacturing a semiconductor device according to claim 15, wherein the first insulating layer and the second insulating layer comprise silicon oxide.

18. The method of manufacturing a semiconductor device according to claim 15, wherein the steps of etching the first insulating layer and the second insulating layer comprise wet etching.

19. The method of manufacturing a semiconductor device according to claim 18, further comprising disposing a protective layer on the semiconductor stack before disposing the first insulating layer, wherein materials of the protective layer and the first insulating layer are different.

20. The method of manufacturing a semiconductor device according to claim 19, wherein the protective layer is used as an etch stop layer during etching the first insulating layer and the second insulating layer.
